(19) United States
(12) Patent Application Publication
(10) Pub. No.: US 2026/0047129 A1
(43) Pub. Date: Feb. 12, 2026

(54) SILICON CARBIDE SEMICONDUCTOR DEVICE

(71) Applicant: DENSO CORPORATION, Kariya-city (JP)

(72) Inventor: Takuma KATANO, Kariya-city (JP)

(21) Appl. No.: 19/365,566

(22) Filed: Oct. 22, 2025

Related U.S. Application Data
(63) Continuation of application No. PCT/JP2024/016352, filed on Apr. 25, 2024.

(30) Foreign Application Priority Data
Apr. 26, 2023 (JP) 2023-072621

(51) Int. Cl. H10D 30/66; H10D 30/01; H10D 62/10; H10D 62/60; H10D 62/832

(52) U.S. Cl. CPC H10D 30/668; H10D 30/665; H10D 62/102; H10D 62/124; H10D 62/60; H10D 62/8325; H10D 30/0297

(57) ABSTRACT

A SiC semiconductor device has a trench gate structure in a semiconductor element. A JFET layer of a first conductivity type and a first deep layer of a second conductivity type are formed in a cell region. An outer periphery termination position of the JFET layer located on the outer periphery side of the cell region is closer to the cell region than an inner periphery termination position of a gate wiring adjacent to the cell region is.

### CROSS REFERENCE TO RELATED APPLICATIONS

The present application is a continuation application of International Patent Application No. PCT/JP2024/016352 filed on Apr. 25, 2024, which designated the U.S. and claims the benefit of priority from Japanese Patent Application No. 2023-72621, filed on Apr. 26, 2023. The entire disclosures of all of the above applications are incorporated herein by reference.

### TECHNICAL FIELD

The present disclosure relates to a silicon carbide (hereinafter referred to as SiC) semiconductor device having a trench gate structure in a semiconductor element.

### BACKGROUND

In a SiC semiconductor device having a MOSFET with a trench gate structure, a gate insulating film is extended to a periphery of a cell region in which the MOSFET is formed, and a field oxide film is disposed thereon. The gate electrode of the MOSFET provided in the cell region is extended onto the gate insulating film and the field insulating film arranged to the periphery of the cell region, and is connected to the gate wiring.

### SUMMARY

According to one aspect of the present disclosure, a silicon carbide semiconductor device includes a substrate made of silicon carbide of a first conductivity type or a second conductivity type. The substrate has: a cell region in which a semiconductor element having a trench gate structure is formed; and a periphery region provided on an outer periphery side surrounding the cell region to have a peripheral breakdown withstanding portion and a connection section located between the peripheral breakdown withstanding portion and the cell region. A first impurity region of a first conductivity type is formed on the substrate to have a lower impurity concentration than the substrate. The cell region includes: a JFET layer made of silicon carbide of a first conductivity type and formed in a surface layer of the first impurity region to have a higher impurity concentration than the first impurity region; a deep layer made of silicon carbide of a second conductivity type and formed in a surface layer of the first impurity region, the JFET layer and the deep layer being arranged alternately in a surface direction of the substrate; a base layer made of silicon carbide of a second conductivity type and formed above the JFET layer and the deep layer; a plurality of gate trenches arranged in one direction to be deeper than the base layer; a gate insulating film formed on an inner wall surface of the gate trench; a gate electrode formed on the gate insulating film in the gate trench; a second impurity region made of silicon carbide of a first conductivity type and formed in a surface layer of the base layer in contact with the trench gate structure and have a higher impurity concentration than the first impurity region; a first electrode electrically connected to the second impurity region and the base layer; and a second electrode electrically connected to the substrate and disposed on a back side of the substrate. The connection section has: a gate insulating film on the first impurity region to extend from the cell region; a gate electrode on the gate insulating film to extend from the cell region; and a gate wiring connected to the gate electrode. An outer periphery termination position which is an end position of the JFET layer located on the outer periphery side of the cell region may be closer to the cell region than an inner periphery termination position which is an end position of the gate wiring adjacent to the cell region is.

### BRIEF DESCRIPTION OF THE DRAWINGS

FIG. 1 is a plan view of a SiC semiconductor device according to a first embodiment.

FIG. 2 is a perspective view of an area RA in FIG. 1 as viewed in a direction II.

FIG. 3 is a cross-sectional view taken along line III-III in FIG. 1.

FIG. 4 is a cross-sectional view taken along line IV-IV in FIG. 1.

FIG. 5 is a cross-sectional view illustrating a displacement current generated in a periphery region.

FIG. 6A is a cross-sectional view showing a manufacturing process of the SiC semiconductor device according to the first embodiment.

FIG. 6B is a cross-sectional view showing a manufacturing process subsequent to FIG. 6A.

FIG. 6C is a cross-sectional view showing a manufacturing process subsequent to FIG. 6B.

FIG. 6D is a cross-sectional view showing a manufacturing process subsequent to FIG. 6C.

FIG. 6E is a cross-sectional view showing a manufacturing process subsequent to FIG. 6D.

FIG. 7 is a cross-sectional view of a SiC semiconductor device according to a second embodiment.

FIG. 8A is a cross-sectional view showing a manufacturing process of the SiC semiconductor device according to the second embodiment.

FIG. 8B is a cross-sectional view showing a manufacturing process subsequent to FIG. 8A.

FIG. 8C is a cross-sectional view showing a manufacturing process subsequent to FIG. 8B.

FIG. 8D is a cross-sectional view showing a manufacturing process subsequent to FIG. 8C.

FIG. 8E is a cross-sectional view showing a manufacturing process subsequent to FIG. 8D.

### DETAILED DESCRIPTION

In a SiC semiconductor device having a MOSFET with a trench gate structure, a gate insulating film is extended to a periphery of a cell region in which the MOSFET is formed, and a field oxide film is disposed thereon. The gate electrode of the MOSFET provided in the cell region is extended onto the gate insulating film and the field insulating film arranged to the periphery of the cell region, and is connected to the gate wiring.

In a SiC semiconductor device configured in this manner, a thin insulating film such as a gate insulating film is easily destroyed by a displacement current that flows during high-speed switching. For this reason, a distance from a source contact in the cell region to a step portion that is the boundary between the gate insulating film and the field insulating film is set short, thereby shortening the distance of the current path. This reduces the current path resistance, and suppresses breakdown of the gate insulating film caused by the displacement current, so as to improve the switching resistance.

However, if the resistance of the SiC semiconductor device is affected at a location other than the step portion of the field oxide film, the effect of reducing the current path resistance cannot be obtained, and the switching resistance cannot be improved. The present disclosure provides a SiC semiconductor device to improve switching withstand capability regardless of the location that determines the withstand capability.

In one aspect of the present disclosure, a SiC semiconductor device has a cell region in which a semiconductor element of a trench gate structure is formed, and a periphery region surrounding the cell region. The periphery region is provided with a peripheral voltage withstanding portion having a peripheral voltage withstand structure and a connection section located between the peripheral voltage withstanding portion and the cell region. The SiC semiconductor device has a substrate made of SiC of a first conductivity type or a second conductivity type. A first impurity region of the first conductivity type is formed on a surface of the substrate to have a lower impurity concentration than the substrate. The cell region has: a JFET layer made of SiC of a first conductivity type formed in a surface layer of the first impurity region to have a higher impurity concentration than the first impurity region; and a deep layer made of SiC of a second conductivity type formed in a surface layer of the first impurity region. The JFET layer and the deep layer are arranged alternately in the surface direction of the substrate. A base layer made of SiC of a second conductivity type is formed on the JFET layer and the deep layer. A gate insulating film is formed on an inner wall surface of a gate trench arranged deeper than the base layer, with one direction as the longitudinal direction. A gate electrode is formed on the gate insulating film in the gate trench. A second impurity region made of SiC of a first conductivity type is formed in contact with the trench gate structure in the surface layer of the base layer to have a higher impurity concentration than the first impurity region. A first electrode is electrically connected to the second impurity region and the base layer. A second electrode is arranged on the back surface of the substrate and electrically connected to the substrate. The connection section includes: a gate insulating film formed on the first impurity region to extend from the cell region; a gate electrode disposed on the gate insulating film to extend from the cell region; and a gate wiring connected to the gate electrode. An outer periphery termination position of the JFET layer, which is an end position on the outer periphery side of the cell region, is located closer to the cell region than an inner periphery termination position of the gate wiring, which is an end position adjacent to the cell region, is.

In this way, the JFET layer is not formed below the gate wiring where the electric field applied to the gate insulating film is likely to be large. The outer periphery termination position of the JFET layer is made closer to the cell region than the inner periphery termination position of the gate wiring is. This structure reduces the impurity concentrations of the p-type and n-type layers that make up the pn junction, so as to reduce the displacement current that occurs when the voltage suddenly increases during switching. Therefore, the electric field concentration caused by the displacement current is alleviated, and the breakdown of the gate insulating film can be suppressed, such that the switching resistance can be improved. This effect can be obtained regardless of the location that determines the resistance. Therefore, it is possible to obtain a SiC semiconductor device capable of improving the switching withstand voltage regardless of the location that determines the withstand voltage.

In a second aspect of the present disclosure, the JFET layer is formed only in the cell region.

In this manner, the JFET layer is formed in the cell region, and the JFET layer is not formed outside of the cell region. Therefore, the pn junction in the outer periphery of the connection section is composed of a low concentration layer and a deep layer. Therefore, the effect of the first aspect can be obtained.

In a third aspect of the present disclosure, the JFET layer is formed in the connection section, and an external portion of the JFET layer located outside the inner periphery termination position, which is the end position of the gate wiring adjacent to the cell region, has a first conductivity type impurity concentration that is equal to or lower than that of the first impurity region.

In this way, when the JFET layer is formed in the connection section, the impurity concentrations of the p-type layer and n-type layer that form the pn junction in the periphery region will be lower by lowering the first conductivity type impurity concentration at location outside the inner periphery termination position of the gate wiring. Therefore, the change per time dV/dt is reduced and the displacement current can be reduced, thereby improving the switching resistance. It is possible to provide a SiC semiconductor device in which the switching resistance can be improved regardless of the location where the resistance is limiting.

Hereinafter, embodiments of the present disclosure will be described with reference to the drawings. In the following embodiments, the same reference numerals are assigned to portions that are the same or equivalent to each other for description.

### First Embodiment

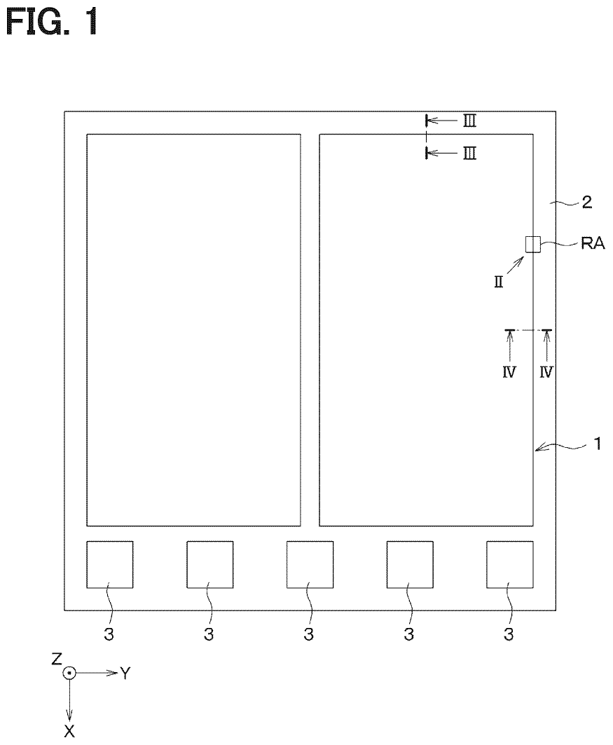

A first embodiment will be described with reference to the drawings. As shown in FIG. 1, the SiC semiconductor device of this embodiment has a cell region 1 which is an active region where an element operates, and a periphery region 2 surrounding the cell region 1.

As shown in FIG. 1, pads 3 are provided below the cell region 1 of the SiC semiconductor device, to control elements in the cell region 1, or detect temperature.

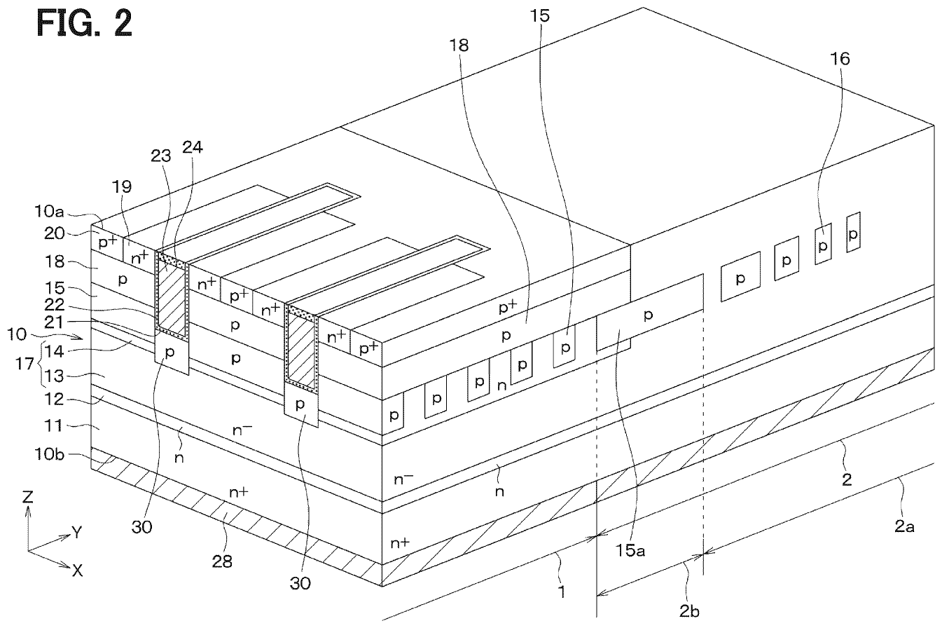

As shown in FIG. 2, the periphery region 2 has a guard ring 2a which corresponds to a peripheral breakdown voltage structure portion in which a peripheral breakdown voltage structure is configured, and a connection section 2b located inward of the guard ring 2a. In other words, the periphery region 2 has the guard ring 2a and the connection section 2b disposed between the cell region 1 and the guard ring 2a.

Hereinafter, the SiC semiconductor device will be described with reference to FIGS. 2 to 4, in which an n-channel vertical MOSFET is provided as a semiconductor element having a trench gate structure in the cell region 1. In the following, one direction in the surface direction of the semiconductor substrate 10 will be referred to as X direction. A direction intersecting the X direction in the surface direction of the semiconductor substrate 10 will be referred to as Y direction. A direction intersecting the X direction and the Y direction will be referred to as Z direction. The X direction, the Y direction, and the Z direction are perpendicular to each other. The Z direction in this embodiment corresponds to a thickness direction of the semiconductor substrate 10, and corresponds to the stacking direction of the substrate 11 and the low concentration layer 13, which will be described later. The Y direction is, for example, <11-20> direction.

The SiC semiconductor device includes the semiconductor substrate 10 in which the vertical MOSFET element is formed. The semiconductor substrate 10 includes various semiconductor layers made of SiC relative to the n+ type substrate 11 made of SiC. In the present embodiment, the substrate 11 has, for example, an off-angle of 0 to 8 degrees with respect to a (0001) Si plane, and has an n-type impurity concentration of, for example, 1.0×10¹⁹/cm³, such as nitrogen or phosphorus. A thickness of the substrate 11 is about 300 um. In case of a vertical MOSFET, the substrate 11 constitutes the drain region.

An n-type buffer layer 12 made of SiC is formed as necessary on the surface of the substrate 11. The buffer layer 12 is formed by epitaxial growth on the surface of the substrate 11. An n-type impurity concentration of the buffer layer 12 is between that of the substrate 11 and that of the low concentration layer 13. The buffer layer 12 has a thickness of about 1 μm.

The n-type low concentration layer 13 made of SiC is formed on the surface of the buffer layer 12 to have an n-type impurity concentration of, for example, 5.0×10¹⁵ to 2.0×10¹⁶/cm³ and a thickness of about 7 μm to 15 μm. The low concentration layer 13 may have a constant impurity concentration along the Z direction, or a concentration distribution, for example, so that the concentration of a portion of the low concentration layer 13 closer to the substrate 11 is higher than that of the other portion farther from the substrate 11. In this embodiment, the low concentration layer 13 corresponds to a first impurity region.

The JFET layer 14 and the first deep layer 15 are formed in the surface layer of the low concentration layer 13 in the cell region 1. In the present embodiment, the JFET layer 14 and the first deep layer 15 are arranged alternately in the Y direction and extend in the X direction, as linear portions. In other words, the JFET layer 14 and the first deep layer 15 have stripe shape extending in the X direction, when seen in a direction normal to the surface of the substrate 11 (hereinafter simply referred to as a normal direction). The normal direction to the surface of the substrate 11 represents a stacking direction of the drift layer 17 and the base layer 18 described later, along the Z direction.

The JFET layer 14 is of n-type with a higher impurity concentration than the low concentration layer 13, and has a thickness of 0.3 to 1.5 μm. In this embodiment, the JFET layer 14 has an n-type impurity concentration of about 5.0×10¹⁶ to 1.0×10¹⁷/cm³. The first deep layer 15 has a p-type impurity concentration of about 2.0×10¹⁷ to 2.0×10¹⁸/cm³.

The first deep layer 15 may have the same depth as the JFET layer 14, or may be deeper or shallower than the JFET layer 14. In this embodiment, the first deep layer 15 is formed shallower than the JFET layer 14. In other words, the first deep layer 15 is formed so that its bottom is located within the JFET layer 14. In other words, the first deep layer 15 is formed such that the JFET layer 14 is located between the first deep layer 15 and the low concentration layer 13. This suppresses the spread of the depletion layer into the JFET layer 14 between the first deep layers 15, thereby reducing the on-resistance. The JFET layer 14 and the first deep layer 15 are formed by appropriately ion-implanting impurity into the surface layer of the low concentration layer 13.

Meanwhile, a surface layer of the low concentration layer 13 in the guard ring 2a of the periphery region 2 has plural p-type guard rings 16 as a peripheral breakdown withstand structure so as to surround the cell region 1. In the present embodiment, the layout of the upper surface of the guard ring 16 is designed to have a rectangular shape in which four corners are rounded, a circular shape, or the like, when seen in the normal direction.

Furthermore, a p-type connecting layer 15a is provided in the surface layer of the low concentration layer 13 in the connection section 2b of the periphery region 2. The connecting layer 15a has an inner end that surrounds the cell region 1, and an outer end disposed up to the boundary position with the guard ring 2a. The connecting layer 15a is formed by extending the first deep layer 15 up to the connection section 2b, and has the same depth and the same p-type impurity concentration as the first deep layer 15.

The JFET layer 14 is formed in a part of the connection section 2b adjacent to the cell region 1, in the periphery region 2, but the JFET layer 14 is not formed on the external side. Therefore, at a position where the JFET layer 14 is formed deeper than the first deep layer 15, the JFET layer 14 is present below the connecting layer 15a adjacent to the cell region 1, but the JFET layer 14 is not present on the external side of the connection section 2b adjacent to the guard ring 2a.

A base layer 18, a source region 19, a contact region 20, etc. are formed on the JFET layer 14 and the first deep layer 15 in the cell region 1.

The base layer 18 is of p-type and is formed on the JFET layer 14 and the first deep layer 15. Therefore, the first deep layer 15 is in a state of being connected to the base layer 18. The base layer 18 has, for example, a p-type impurity concentration of 5.0×10¹⁶ to 2.0×10¹⁹/cm³ and a thickness of about 2.0 μm.

The source region 19 is of n+ type and is formed in the surface layer of the base layer 18. The contact region 20 is of p+type and is formed in the surface layer of the base layer 18. Specifically, the source region 19 is formed in contact with a side surface of a trench 21 (described later), and the contact region 20 is formed on the opposite side of the source region 19 through the trench 21. In this embodiment, the source region 19 has an n-type impurity concentration in the surface layer, that is, a surface concentration of, for example, 1.0×10¹⁸/cm³, and a thickness of about 0.3 μm. The contact region 20 has a p-type impurity concentration in the surface layer, that is, a surface concentration of, for example, 1.0×10²¹/cm³, and a thickness of about 0.3 μm. In this embodiment, the source region 19 corresponds to a second impurity region.

The base layer 18, the contact region 20, and a surface portion of the low concentration layer 13 are formed on the low concentration layer 13, the JFET layer 14, the first deep layer 15, and the connecting layer 15a in the connection section 2b of the periphery region 2. In the internal side of the connection section 2b, the base layer 18 and the contact region 20 are formed on the connecting layer 15a and extend from the cell region 1. In the external side of the connection section 2b, the base layer 18 and the contact region 20 are not formed, and the surface portion of the low concentration layer 13 is formed. In other words, in this embodiment, the base layer 18 and contact region 20 in the periphery region 2 are extended from the cell region 1 and formed halfway into the connection section 2b, but not formed in the external side of the connection section 2b adjacent to the guard ring 2a. In addition, from the boundary position between the cell region 1 and the periphery region 2 to halfway through the connection section 2b, the entire surface layer of the connection section 2b is made into the contact region 20. The entire surface layer at the external side of the connection section 2b adjacent to the guard ring 2a is made into the low concentration layer 13.

As described above, in this embodiment, the semiconductor substrate 10 includes the substrate 11, the buffer layer 12, the low concentration layer 13, the JFET layer 14, the first deep layer 15, the base layer 18, the source region 19, and the contact region 20. Since each layer of the semiconductor substrate 10 is made of SiC, it can be said that the semiconductor substrate 10 is made of SiC. In this embodiment, at the cell region 1 and the internal side of the connection section 2b, the one surface 10a of the semiconductor substrate 10 is composed of the source region 19, the contact region 20, etc., and the other surface 10b of the semiconductor substrate 10 is composed of the substrate 11.

In this embodiment, the JFET layer 14, the first deep layer 15, the connecting layer 15a, the guard ring 16, the base layer 18, the source region 19, and the contact region 20 are made of ion-implanted layers formed by ion implantation.

In the cell region 1, the trench 21 is formed in the semiconductor substrate 10, penetrating the source region 19, the base layer 18, etc., and reaching the JFET layer 14 and the first deep layer 15 from the one surface 10a. The trench 21 corresponds to a gate trench, and has a depth such that its bottom surface is located within the JFET layer 14 and the first deep layer 15, and a width of, for example, 0.4 to 0.8 μm.

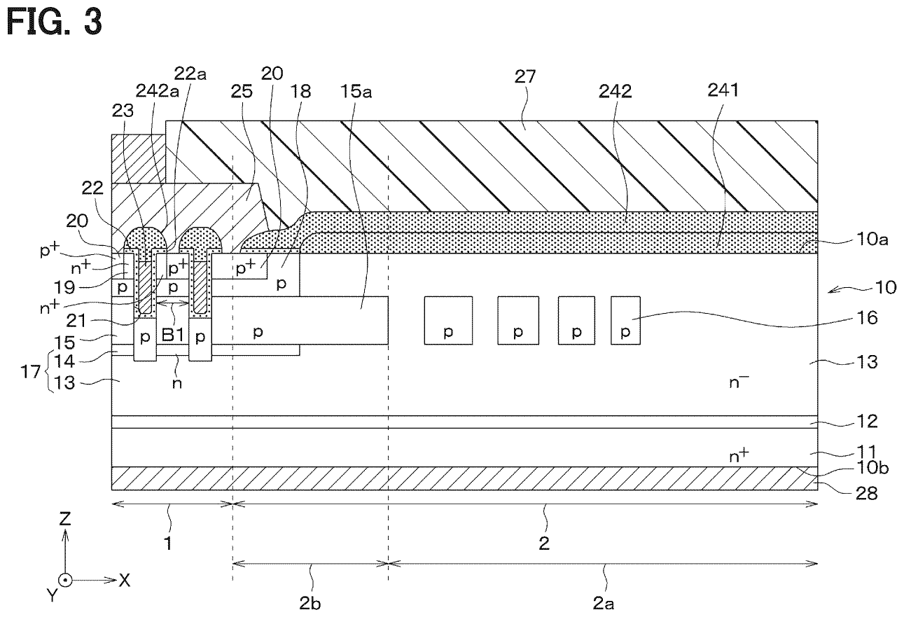

The trenches 21 are arranged at equal interval B1 in the X direction, as shown in FIG. 3, and extend along the Y direction, to form a stripe shape. In the present embodiment, the longitudinal direction of the trench 21 is orthogonal to the longitudinal direction of the first deep layer 15.

The second deep layer 30 serving as an electric field relaxation layer is formed at the bottom of the trench 21 to be in contact with the bottom surface of the trench 21. In this embodiment, the second deep layer 30 is composed of a p-type layer having a lower impurity concentration than the first deep layer 15. Specifically, the second deep layer 30 is formed along the longitudinal direction of the trench 21. In other words, the second deep layer 30 extends along the Y direction intersecting with the first deep layer 15. Moreover, the second deep layer 30 of this embodiment is formed to penetrate through the JFET layer 14 and the first deep layer 15 and have a bottom surface reaching the low concentration layer 13.

It is possible to suppress the penetration of electric field into the gate insulating film 22 located at the bottom of the trench 21, by forming the second deep layer 30 along the bottom surface of the trench 21. Therefore, it is possible to suppress the breakdown of the oxide film. Furthermore, the electrostatic capacitance between the gate electrode 23 and the lower electrode 28, that is, the feedback capacitance, can be reduced by forming the second deep layer 30 to be in contact with the bottom surface of the trench 21. Thus, the switching speed can be improved. Furthermore, since the second deep layer 30 is formed to penetrate the JFET layer 14 and the first deep layer 15 and have its bottom surface reach the low concentration layer 13, the electric field is restricted from creeping up to the JFET layer 14 located between the second deep layers 30, thereby improving the breakdown voltage. In addition, since breakdown is more likely to occur in the second deep layer 30 that protrudes downward when an overvoltage is applied, breakdown is more likely to occur in the cell region 1, and the avalanche resistance can be improved.

The second deep layer 30 may be divided into plural parts along the Y direction. However, the second deep layer 30 is formed to be electrically connected to the base layer 18 via the first deep layer 15.

A gate insulating film 22 is formed on the inner wall surface of the trench 21, and a gate electrode 23 made of doped Poly-Si or the like is formed on the gate insulating film 22. As a result, a trench gate structure is formed. Although not particularly limited, the gate insulating film 22 is formed by thermally oxidizing the inner wall surface of the trench 21 or by forming an insulating film by a CVD (abbreviation of chemical vapor deposition) method. The gate insulating film 22 has a thickness of about 100 nm on both the side and bottom surfaces of the trench 21.

The gate insulating film 22 is formed on the inner wall surface of the trench 21 as well as on the one surface 10a of the semiconductor substrate 10. In the cell region 1, a contact hole 22a is formed in the gate insulating film 22, and the source region 19 and the contact region 20 are exposed.

A field oxide film 241 is formed on the one surface 10a of the semiconductor substrate 10 so as to surround the outer edge of the cell region 1, and an interlayer insulating film 242 is further formed to cover the gate electrode 23, the gate insulating film 22, the field oxide film 241, and the like. The interlayer insulating film 242 is made of borophosphosilicate glass (BPSG). In FIG. 2, the field oxide film 241, the interlayer insulating film 242, and the like located on the one surface 10a of the semiconductor substrate 10 are omitted.

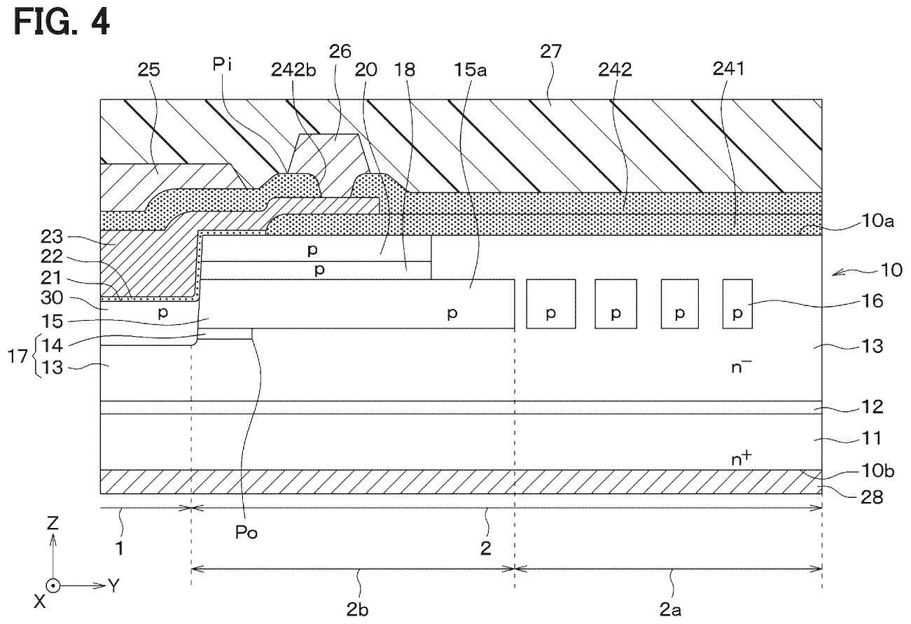

As shown in FIG. 3, the interlayer insulating film 242, in the cell region 1, has a contact hole 242a which communicates with the contact hole 22a and exposes the source region 19 and the contact region 20. As shown in FIG. 4, the interlayer insulating film 242 has a contact hole 242b to expose a portion of the gate electrode 23 that extends to the connection section 2b.

An upper electrode 25 is formed on the interlayer insulating film 242 and is electrically connected to the source region 19 and the contact region 20 through the contact hole 22a and the contact hole 242a. The upper electrode 25 is adapted to be electrically connected to the outside. In the present embodiment, the upper electrode 25 corresponds to a first electrode. A gate wiring 26 to be electrically connected to the gate electrode 23 through the contact hole 242b is formed on the interlayer insulating film 242. Although not shown in FIG. 1, the gate wiring 26 is formed along the outer edge of the cell region 1, for example, along each of the right, left and lower sides of the SiC semiconductor device that is a rectangular chip shown in FIG. 1.

As described above, the JFET layer 14 is formed only in the cell region 1 and the connection section 2b adjacent to the cell region 1, but is not disposed below the gate wiring 26. In other words, as shown in FIG. 4, the outer periphery termination position Po of the JFET layer 14, which is located on the outer periphery side of the cell region 1, is arranged to be closer to the cell region 1 than the inner periphery termination position Pi of the gate wiring 26, which is located adjacent to the cell region 1. Further, at the external side of the inner periphery termination position Pi, the connecting layer 15a is formed or the low concentration layer 13 is formed.

The upper electrode 25, in the present embodiment, is made of metals such as Ni/Al. Among the metals, a portion in contact with n-type SiC to constitute the source region 19 is made of metal capable of making ohmic contact with n-type SiC. At least a portion of the metals in contact with p-type SiC, i.e., the contact region 20, is made of metal that can make ohmic contact with p-type SiC. The gate wiring 26 may have the same structure as the upper electrode 25, or may be made of Al—Si or the like.

Furthermore, a protective film 27 made of polyimide or the like is formed to cover the connection section 2b and the guard ring 2a. In this embodiment, the protective film 27 is formed from the periphery region 2 to the external side of the cell region 1 in order to suppress the occurrence of creeping discharge between the upper electrode 25 and the lower electrode 28. Specifically, the protective film 27 is formed in the cell region 1 to cover a portion of the upper electrode 25 adjacent to the periphery region 2, while exposing the upper electrode 25 on the internal side.

The lower electrode 28 is formed on the other surface 10b of the semiconductor substrate 10, and is electrically connected to the substrate 11. In the present embodiment, the lower electrode 28 corresponds to a second electrode.

In the SiC semiconductor device, according to the present embodiment, MOSFET of an n-channel type inverted trench gate structure is formed.

In the present embodiment, the n-type, the n⁺-type, and the n⁻-type correspond to a first conductivity type, and the p-type and the p⁺-type correspond to a second conductivity type. Next, the operation of the SiC semiconductor device will be described.

First, in the SiC semiconductor device, in the off state before a gate voltage is applied to the gate electrode 23, no inversion layer is formed in the base layer 18. Therefore, even if a positive voltage, for example, 1600 V, is applied to the lower electrode 28, electrons do not flow from the source region 19 into the base layer 18, and no current flows between the upper electrode 25 and the lower electrode 28.

In a state before a gate voltage is applied to the gate electrode 23, an electric field is applied between the drain and the gate, and an electric field concentration may occur at a bottom of the gate insulating film 22. However, in the SiC semiconductor device, the first deep layer 15 and the JFET layer 14 are provided at position deeper than the trench 21. Therefore, a depletion layer formed between the first deep layer 15 and the JFET layer 14 suppresses the rising of equipotential lines due to an influence of the drain voltage, and makes a high electric field difficult to enter the gate insulating film 22. Furthermore, since the second deep layer 30 serving as an electric field relaxation layer is provided at the bottom of the trench 21, it becomes more difficult for a high electric field to penetrate into the gate insulating film 22. Therefore, in the present embodiment, breakdown of the gate insulating film 22 can be inhibited.

Furthermore, when a predetermined gate voltage is applied to the gate electrode 23, a channel is formed on the surface of the base layer 18 in contact with the trench 21. Therefore, electrons injected from the upper electrode 25 pass through the channel formed from the source region 19 to the base layer 18, then pass through the JFET layer 14 to the low concentration layer 13, and then pass through the substrate 11 as the drain layer to the lower electrode 28. As a result, a current flows between the upper electrode 25 and the lower electrode 28, and the SiC semiconductor device is turned on. In this embodiment, since electrons that have passed through the channel pass through the JFET layer 14 and the low concentration layer 13 and flow to the substrate 11, it can be said that the drift layer 17 has the JFET layer 14 and the low concentration layer 13.

As described above, the JFET layer 14 is disposed only in the cell region 1 and the connection section 2b adjacent to the cell region 1, and is not disposed at the external side. With this configuration, it is possible to improve the switching tolerance when the vertical MOSFET is turned on and off based on the application of a gate voltage. The switching resistance will be described below.

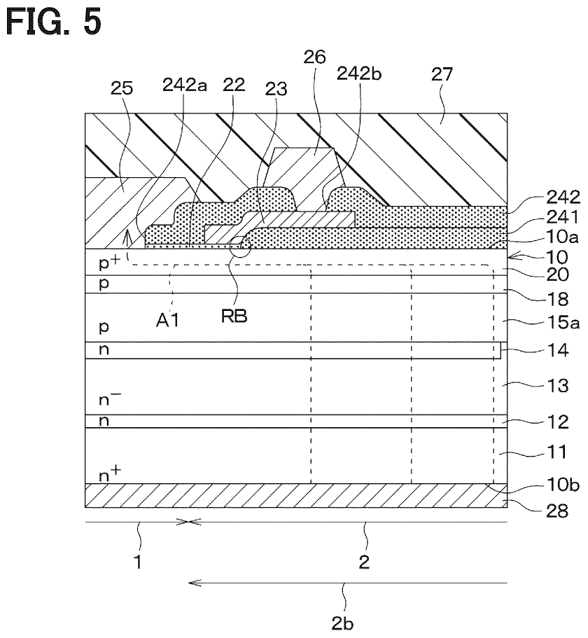

FIG. 5 shows a comparative example where the JFET layer 14 is formed not only in the cell region 1 but also in the connection section 2b. FIG. 5 shows the displacement current A1 at a cross-section of the SiC semiconductor device taken along the Y direction, which is the longitudinal direction of the trench gate structure, between the trench gate structures adjacent to each other, i.e., at a position other than the trench gate structure.

During high-speed switching of the vertical MOSFET, as indicated by the dashed arrow in FIG. 5, a displacement current A1 flows. That is, in the periphery region 2, the electron propagates from the lower electrode 28 through the substrate 11, the low concentration layer 13 and the JFET layer 14 to the connecting layer 15a. From there, the displacement current A1 flows to the base layer 18 and the contact region 20, and moves in the surface direction of the semiconductor substrate 10 within the contact region 20 to the upper electrode 25. The displacement current A1 at this time is proportional to the time change dV/dt of the high voltage generated during switching. As the impurity concentration of the p-type and n-type layers constituting the pn junction in the periphery region 2 increases, the source-drain capacitance increases, and the time change dV/dt increases, causing the displacement current A1 to increase. When the JFET layer 14 is formed in the connection section 2b as in the comparative example shown in FIG. 5, the pn junction is formed by the JFET layer 14 and the connecting layer 15a, and the impurity concentration becomes high. Therefore, when the displacement current A1 becomes large and electric field concentration occurs, the thin gate insulating film 22 is destroyed, and switching resistance cannot be obtained. The dielectric breakdown occurs at the boundary position RB between the gate insulating film 22 and the field oxide film 241 shown in FIG. 5.

In contrast, as in the present embodiment, since the JFET layer 14 is not provided at least on the external side of the connection section 2b, the pn junction in that location will be formed by the low concentration layer 13 and the first deep layer 15. Due to this structure, in this embodiment, the impurity concentration of the p-type layer and n-type layer that make up the pn junction is smaller than in the comparative example, and the displacement current A1 that occurs when the voltage suddenly increases during switching can be reduced. This reduces the electric field concentration caused by the displacement current A1, and suppresses breakdown of the gate insulating film 22, so as to improve the switching resistance.

The electric field applied to the gate insulating film 22 below the gate wiring 26 tends to be large. For this reason, it is preferable that the JFET layer 14 is not formed below the gate wiring 26, and that the outer periphery termination position Po, which is the end position of the JFET layer 14 on the outer periphery side of the cell region 1, is located closer to the cell region 1 than the inner periphery termination position Pi of the gate wiring 26 is. With such a structure, the breakdown of the gate insulating film 22 can be further suppressed, and the switching resistance can be improved.

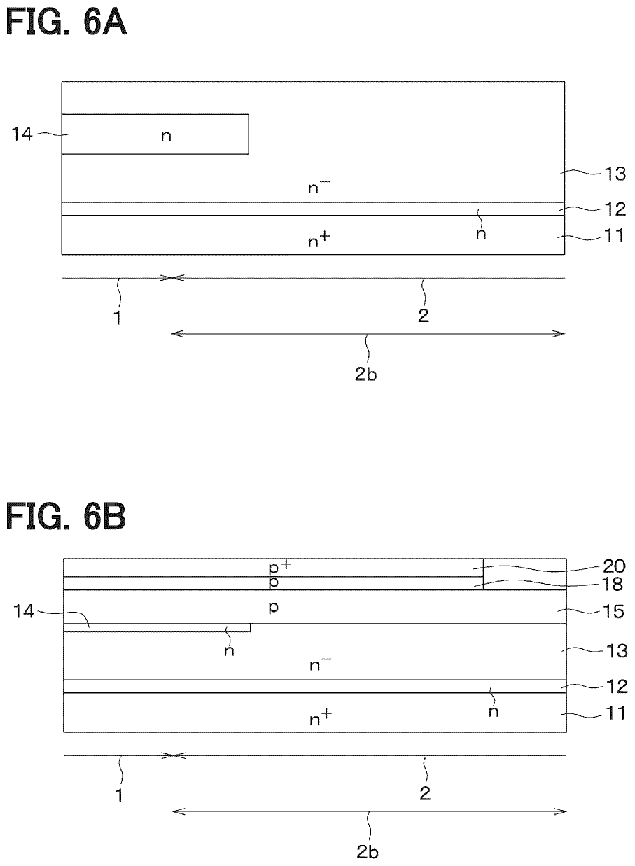

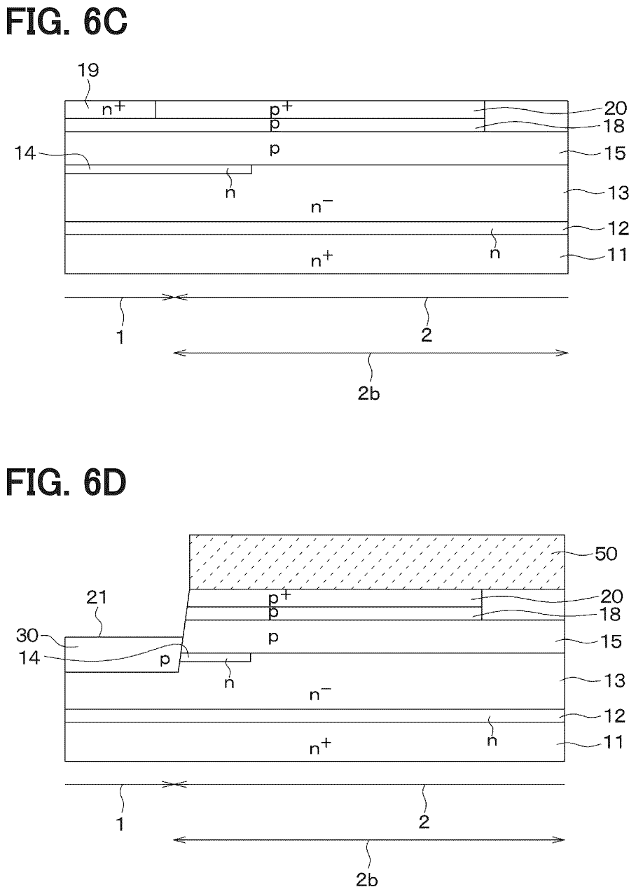

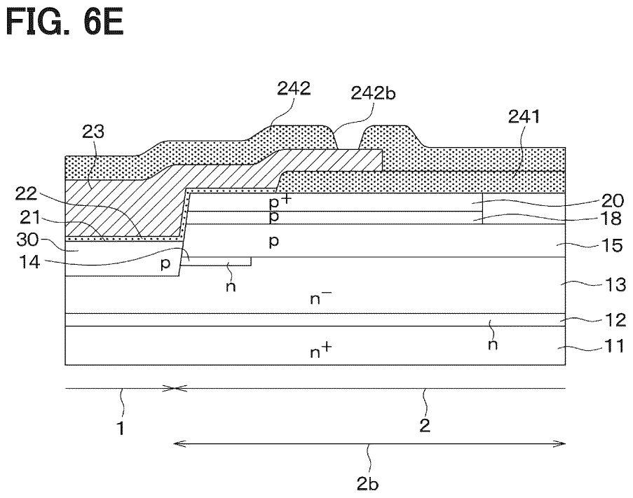

Next, a method for manufacturing the SiC semiconductor device according to the present embodiment will be described with reference to FIGS. 6A to 6E showing manufacturing processes corresponding to the cross-section of the cell region 1 and the connection section 2b in FIG. 4.

First, as shown in FIG. 6A, a substrate 11 is prepared, and then a buffer layer 12 and a low concentration layer 13 are epitaxially grown on one surface of the substrate 11. Then, a mask (not shown) having an opening corresponding to the JFET layer 14 is placed on the surface of the low concentration layer 13, and then n-type impurity ion is implanted to form the JFET layer 14.

Subsequently, a mask (not shown) having an opening corresponding to the first deep layer 15 is formed, and then p-type impurity ion is implanted to form the first deep layer 15 as shown in FIG. 6B. At this time, the JFET layer 14 is formed up to the portion that will become the first deep layer 15, but by increasing the dose of the p-type impurity, the p-type can be driven back to form the first deep layer 15. Moreover, after forming a mask (not shown) having an opening corresponding to the base layer 18, p-type impurity ion is implanted to form the base layer 18. Furthermore, a mask having an opening corresponding to the contact region 20 is used to further ion-implant p-type impurity to form the contact region 20 on the base layer 18.

Thereafter, a mask (not shown) having an opening corresponding to the source region 19 is formed, and then n-type impurity ion is implanted to form the source region 19 as shown in FIG. 6C. At this time, the contact region 20 is formed up to the portion that will become the source region 19, but by increasing the dose of the n-type impurity, the source region 19 can be formed by driving the n-type impurity back.

Next, as shown in FIG. 6D, a mask 50 having an opening corresponding to the trench 21 is placed, and then the trench 21 is formed by dry etching. Furthermore, using the same mask 50, p-type impurity is ion-implanted to form the second deep layer 30 at the bottom of the trench 21.

Subsequently, as shown in FIG. 6E, the gate insulating film 22 is formed by thermal oxidation or CVD, and then the gate electrode 23 is formed by depositing and patterning doped polysilicon. Furthermore, after the steps of forming the field oxide film 241 and the interlayer insulating film 242 are performed, the contact hole 242a, 242b is formed in the interlayer insulating film 242. Thereafter, the steps of forming the upper electrode 25 and the gate wiring 26, the step of forming the protective film 27, and the step of forming the lower electrode 28 on the back surface of the substrate 11 are carried out by conventional steps. Thereby, the SiC semiconductor device according to the present embodiment is completed.

In the SiC semiconductor device, the JFET layer 14 is formed in the connection section 2b adjacent to the cell region 1, but the JFET layer 14 is not formed on the external side of the connection section 2b away from the cell region 1. Moreover, the JFET layer 14 is not disposed below the gate wiring 26 in the connection section 2b, but is disposed only between the cell region 1 and the gate wiring 26.

In the SiC semiconductor device of the present embodiment, the JFET layer 14 is formed in the internal side of the connection section 2b adjacent to the cell region 1, but the JFET layer 14 is not formed on the external side. Therefore, the pn junction in the external side of the connection section 2b is formed by the low concentration layer 13 and the first deep layer 15. This structure reduces the impurity concentrations of the p-type and n-type layers that make up the pn junction, making it possible to reduce the displacement current A1 that occurs when the voltage suddenly increases during switching. Thus, the electric field concentration caused by the displacement current A1 is alleviated, the breakdown of the gate insulating film 22 can be suppressed, and the switching resistance can be improved. This effect can be obtained regardless of the location that determines the resistance. Therefore, it is possible to obtain a SiC semiconductor device capable of improving the switching withstand voltage regardless of the location that determines the withstand voltage. Furthermore, since the switching resistance can be improved, the switching speed of the vertical MOSFET can be increased.

The electric field applied to the gate insulating film 22 is likely to be large below the gate wiring 26, but the JFET layer 14 is not formed in that area, and the outer periphery termination position Po of the JFET layer 14 is arranged to be closer to the cell region 1 than the inner periphery termination position Pi of the gate wiring 26 is. Therefore, the breakdown of the gate insulating film 22 can be further suppressed, and the switching resistance can be improved.

Furthermore, when the distance of the current path is shortened as in a comparison example, the ends of structures such as source contact, field oxide film, and trench become crowded together, making it difficult to manufacture each component with precision. In this case, the manufacturing process is unstable and the yield is reduced. In contrast, according to the present embodiment, the switching resistance can be improved regardless of the distance of the current path, and therefore a decrease in yield can be suppressed.

Furthermore, since the switching tolerance can be improved simply by limiting the formation position of the JFET layer 14 to the cell region 1 and the connection section 2b adjacent to the cell region 1, it is only necessary to change the mask for forming the JFET layer 14 compared to a conventional manufacturing method. Therefore, it is possible to simplify the manufacturing process.

### Second Embodiment

A second embodiment is described. This embodiment is different from the first embodiment in that the formation range of the JFET layer 14 is changed, and other points are the same as those in the first embodiment, so only the points that are different from the first embodiment will be described.

In the first embodiment, the JFET layer 14 is formed in the cell region 1 and in the connection section 2b adjacent to the cell region 1. In the present embodiment, however, the JFET layer 14 is formed only in the cell region 1.

In the first embodiment, the formation ranges of the ion implantation layers for forming the JFET layer 14 and the source region 19 are set separately. In contrast to this, in this embodiment, the formation ranges of the ion implantation layers for forming the JFET layer 14 and the source region 19 are made uniform, when seen in the normal direction to the surface of the substrate 11.

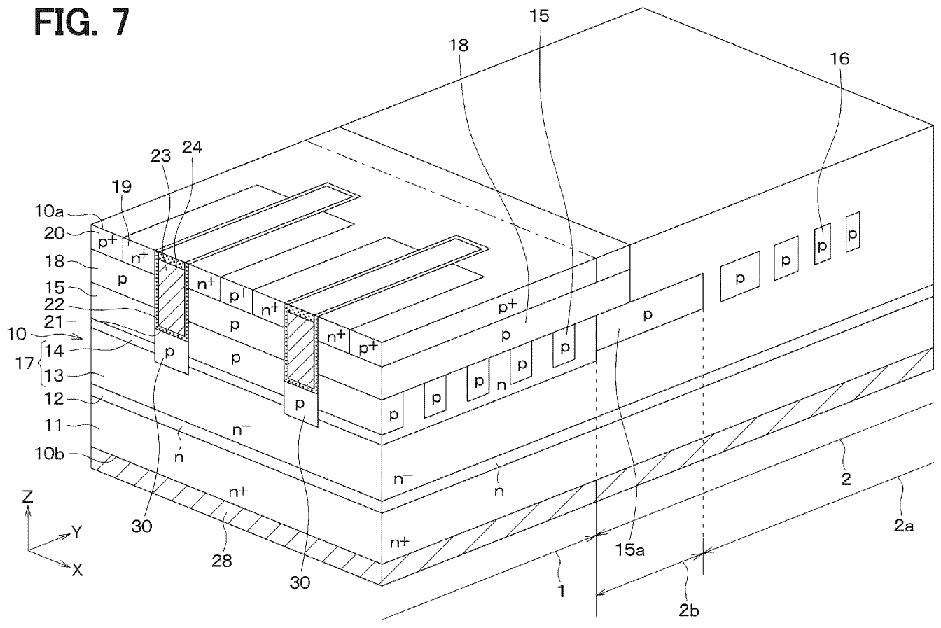

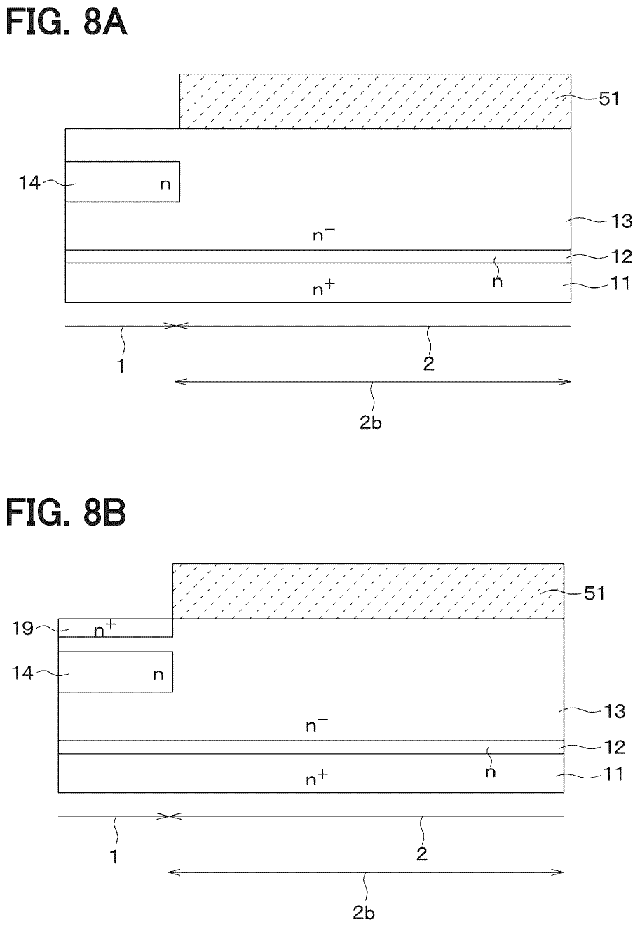

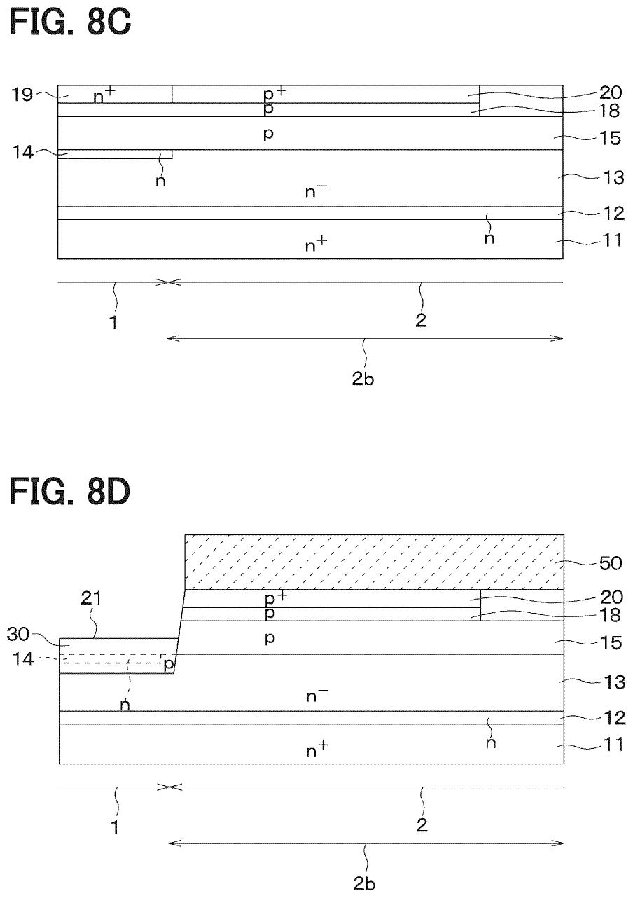

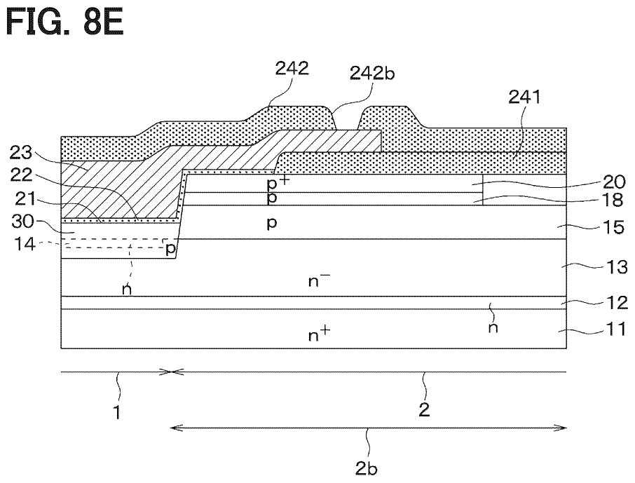

Specifically, as shown in FIG. 7, the JFET layer 14 is formed only in the cell region 1, and the JFET layer 14 is not formed in the periphery region 2. The JFET layer 14 is not formed in the connection section 2b. In addition, the area of the ion implantation layer for forming the JFET layer 14 is limited to the cell region 1 only. As shown in FIG. 8B, which will be described later, the range in which n-type impurity is ion-implanted for forming the source region 19 is set to be the same as the range in which the JFET layer 14 is formed.

The formation range of the ion-implanted layer for forming the JFET layer 14 means the entire range in which ions of n-type impurity are implanted when forming the JFET layer 14, as viewed in the normal direction of the substrate 11. This range also includes a portion that becomes the p-type first deep layer 15 due to the return of the p-type impurity. The range in which the ion-implanted layer is formed for forming the source region 19 means the entire range in which the n-type impurity ions are implanted when the source region 19 is formed, as viewed in the normal direction of the substrate 11. This range also includes a portion that becomes the p-type contact region 20 due to the return of the p-type impurity. Furthermore, making the formation range of the ion implantation layer uniform means that it is preferably the same, but is manufactured with the aim of having the same formation range, and manufacturing errors may be included. The single chain line in FIG. 7 indicates the range in which n-type impurity ions are implanted when forming the source region 19.

In this way, by aligning the formation ranges of the ion implantation layers when forming the JFET layer 14 and the source region 19, a common ion implantation mask can be used when forming the JFET layer 14 and the source region 19 by ion implantation. A method of manufacturing the SiC semiconductor device according to the present embodiment will be described with reference to FIGS. 8A to 8E illustrating manufacturing steps corresponding to the cross-section of the cell region 1 and the connection section 2b in FIG. 4.

First, in the step shown in FIG. 8A, the JFET layer 14 is formed, after the buffer layer 12 and the low concentration layer 13 are formed on the substrate 11 in the same manner as in FIG. 6A. At this time, a mask 51 having an opening corresponding to the JFET layer 14 is placed on the surface of the low concentration layer 13, and then n-type impurity is ion-implanted to form the JFET layer 14, so that ion implantation is performed only in the cell region 1. Subsequently, as shown in FIG. 8B, the mask 51 used in forming the JFET layer 14 is used to perform ion implantation of n-type impurity to form the source region 19. The JFET layer 14 and the source region 19 are formed to different implantation depths by changing the ion implantation energy.

Subsequently, in a process shown in FIG. 8C, the first deep layer 15, the base layer 18, and the contact region 20 are formed by performing a process similar to that shown in FIG. 6C. When forming the contact region 20, the source region 19 is formed up to the portion that will become the contact region 20, but by increasing the dose of the p-type impurity, it is possible to drive it back to the p-type and form the contact region 20.

Furthermore, as a step shown in FIG. 8D, a step similar to that shown in FIG. 6D is performed to form the trench 21, and then the second deep layer 30 is formed. Furthermore, by performing a process similar to that of FIG. 6E as the process shown in FIG. 8E, the process of forming the gate insulating film 22, the process of forming the gate electrode 23, the process of forming the field oxide film 241 and the interlayer insulating film 242, and the process of forming the contact hole 242a, 242b in the interlayer insulating film 242 are performed. Thereafter, the steps of forming the upper electrode 25 and the gate wiring 26, the step of forming the protective film 27, and the step of forming the lower electrode 28 on the back surface of the substrate 11 are carried out. Thereby, the SiC semiconductor device according to the present embodiment is completed.

As described above, in this embodiment, the formation ranges of the ion implantation layers for forming the JFET layer 14 and the source region 19 are made uniform. This allows the use of a common ion implantation mask for the JFET layer 14 and the source region 19, which makes it possible to simplify the manufacturing process and reduce manufacturing costs.

### Other Embodiments

Although the present disclosure has been described in accordance with the embodiments, it is understood that the present disclosure is not limited to such embodiments or structures. The present disclosure encompasses various modifications and variations within the scope of equivalents. In addition, while the various elements are shown in various combinations and configurations, which are exemplary, other combinations and configurations, including more, less or only a single element, are also within the spirit and scope of the present disclosure.

In the embodiments, the connection section 2b includes the base layer 18 and the contact region 20 in the surface layer of the low concentration layer 13. The connection section 2b may not include one or both of the base layer 18 and the contact region 20. When the base layer 18 is formed only in the cell region 1, the base layer 18 can be formed using the ion implantation mask for the JFET layer 14 and the source region 19 as in the second embodiment. In this way, the same mask can be used for the base layer 18 in addition to the JFET layer 14 and the source region 19, which further simplifies the manufacturing process and reduces manufacturing costs.

In the first embodiment, the outer periphery termination position Po of the JFET layer 14 in the connection section 2b is closer to the cell region 1 than the inner periphery termination position Pi of the gate wiring 26 is, and the connecting layer 15a is formed or the low concentration layer 13 is formed at the external side. In other words, the JFET layer 14 is not formed at the external side of the inner periphery termination position Pi of the gate wiring 26. Alternatively, the JFET layer 14 may be formed on the external side of the inner periphery termination position Pi of the gate wiring 26 so that the n-type impurity concentration in that portion is equal to or lower than that of the low concentration layer 13. In this way, even if the JFET layer 14 is formed, when the n-type impurity concentration is lowered at the external side the inner periphery termination position Pi of the gate wiring 26, the impurity concentrations of the p-type layer and n-type layer that constitute the pn junction in the periphery region 2 will be lowered, and the source-drain capacitance can be reduced. Therefore, the same effect as in the first embodiment can be obtained.

In the embodiments, the bottom surface of the second deep layer 30 may be shallower and positioned within the JFET layer 14 and the first deep layer 15. In other words, the second deep layer 30 may be formed not to reach the low concentration layer 13. This makes it difficult for a depletion layer to extend from the second deep layer 30, thereby making it possible to reduce the on-resistance.

In the first embodiment, the JFET layer 14, the first deep layer 15, the base layer 18, the contact region 20, and the source region 19 are formed by ion implantation. A part or all of the JFET layer 14, the first deep layer 15, the base layer 18, the contact region 20, and the source region 19 may be composed of an epitaxial layer formed by epitaxial growth.

In the embodiments, the base layer 18 is formed on the surface of the JFET layer 14 and the first deep layer 15. An n-type current spreading layer having a higher n-type impurity concentration than the low concentration layer 13 may be formed between them. In this case, in addition to the current spreading layer, p-type coupling layers may be formed on both sides of the trench 21, and the base layer 18 may be formed on the current spreading layer and the coupling layer. In this case, the first deep layer 15 and the base layer 18 are connected to each other through the coupling layer. The low concentration layer 13, the JFET layer 14, and the current spreading layer are connected to each other, so as to form the drift layer 17. Even in the case of such a structure, the second deep layer 30 may be formed deeper than the first deep layer 15, or may be formed to a depth within the thickness of the first deep layer 15.

In the embodiments, the semiconductor element having the cell region 1 is an n-channel type vertical MOSFET with a trench gate structure in which the first conductivity type is n-type and the second conductivity type is p-type. However, this is merely one example, and a p-channel type vertical MOSFET having a trench gate structure in which the conductivity type of each component is inverted from that of an n-channel type may also be used. Furthermore, instead of a vertical MOSFET, a vertical IGBT having a similar structure may be used. In the case of an IGBT, the conductivity type of the substrate 11 in each of the embodiments is changed from n-type to p-type, and the rest is the same as the vertical MOSFET described in the embodiments.

When indicating a crystal orientation, a bar (-) should normally be placed above the desired number. However, due to limitations on expression based on electronic filing, a bar is placed before the desired number in this specification.

What is claimed is:

1. A silicon carbide semiconductor device comprising:
a substrate made of silicon carbide of a first conductivity type or a second conductivity type and having
a cell region in which a semiconductor element having a trench gate structure is formed, and
a periphery region provided on an outer periphery surrounding the cell region to have a peripheral breakdown withstanding portion and a connection section located between the peripheral breakdown withstanding portion and the cell region; and
a first impurity region of a first conductivity type formed on the substrate to have a lower impurity concentration than the substrate, wherein
the cell region includes:
a JFET layer made of silicon carbide of a first conductivity type and formed in a surface layer of the first impurity region to have a higher impurity concentration than the first impurity region;
a deep layer made of silicon carbide of a second conductivity type and formed in a surface layer of the first impurity region, the JFET layer and the deep layer being arranged alternately in a surface direction of the substrate;
a base layer made of silicon carbide of a second conductivity type and formed above the JFET layer and the deep layer;
a plurality of gate trenches arranged in one direction to be deeper than the base layer;
a gate insulating film formed on an inner wall surface of the gate trench;
a gate electrode formed on the gate insulating film in the gate trench;
a second impurity region made of silicon carbide of a first conductivity type and formed in a surface layer of the base layer in contact with the trench gate structure and have a higher impurity concentration than the first impurity region;
a first electrode electrically connected to the second impurity region and the base layer; and
a second electrode electrically connected to the substrate and disposed on a back side of the substrate,
the connection section has:
a gate insulating film on the first impurity region to extend from the cell region;
a gate electrode on the gate insulating film to extend from the cell region; and
a gate wiring connected to the gate electrode, and
an outer periphery termination position which is an end position of the JFET layer located on an outer periphery side of the cell region is closer to the cell region than an inner periphery termination position which is an end position of the gate wiring adjacent to the cell region is.

2. The silicon carbide semiconductor device according to claim 1, wherein the JFET layer is formed only in the cell region.

3. The silicon carbide semiconductor device according to claim 1, wherein a formation range of an ion implantation layer for forming the JFET layer and a formation range of an ion implantation layer for forming the second impurity region are uniform, when seen in a normal direction to a surface of the substrate.

4. The silicon carbide semiconductor device according to claim 1, wherein a formation range of an ion implantation layer for forming the JFET layer, a formation range of an ion implantation layer for forming the second impurity region, and a formation range of an ion implantation layer for forming the base layer are uniform, when seen in a normal direction to a surface of the substrate.

5. A silicon carbide semiconductor device comprising:
a substrate made of silicon carbide of a first conductivity type or a second conductivity type and having
a cell region in which a semiconductor element having a trench gate structure is formed, and
a periphery region provided on an outer periphery surrounding the cell region to have a peripheral breakdown withstanding portion and a connection section located between the peripheral breakdown withstanding portion and the cell region; and
a first impurity region of a first conductivity type formed on the substrate to have a lower impurity concentration than the substrate, wherein
the cell region includes:
a JFET layer made of silicon carbide of a first conductivity type and formed in a surface layer of the first impurity region to have a higher impurity concentration than the first impurity region;
a deep layer made of silicon carbide of a second conductivity type and formed in a surface layer of the first impurity region, the JFET layer and the deep layer being arranged alternately in a surface direction of the substrate;
a base layer made of silicon carbide of a second conductivity type and formed above the JFET layer and the deep layer;
a plurality of gate trenches arranged in one direction to be deeper than the base layer;
a gate insulating film formed on an inner wall surface of the gate trench;
a gate electrode formed on the gate insulating film in the gate trench;
a second impurity region made of silicon carbide of a first conductivity type and formed in a surface layer of the base layer in contact with the trench gate structure and have a higher impurity concentration than the first impurity region;
a first electrode electrically connected to the second impurity region and the base layer; and
a second electrode electrically connected to the substrate and disposed on a back side of the substrate,
the connection section has:
a gate insulating film on the first impurity region to extend from the cell region;
a gate electrode on the gate insulating film to extend from the cell region; and
a gate wiring connected to the gate electrode, and
the JFET layer is formed in the connection section, and a portion of the JFET layer located outward of an inner periphery termination position, which is an end position of the gate wiring adjacent to the cell region, has a first conductivity type impurity concentration that is equal to or lower than that of the first impurity region.
